(19) United States
(12) Patent Application Publication
(10) Pub. No.: US 2009/0059481 A1
(43) Pub. Date: Mar. 5, 2009

(54) Protective enclosure for personal electronic devices

(76) Inventor: Alan R. Taylor, Myakka City, FL (US)

Correspondence Address: CHARLES J. PRESCOTT, P.A., SUITE 115, 2033 WOOD STREET, SARASOTA, FL, 34237, US

(21) Appl. No.: 11/897,784

(22) Filed: Aug. 31, 2007

(51) Int. Cl. H05K 7/00

(52) U.S. Cl. 361/679

(57) ABSTRACT

A protective enclosure for a small hand or body carryable personal electronic devices such as a well-known IPOD or IPHONE. A two-part generally rectangular housing includes front and back covers formed of high-impact thin-wall molded material and sized to protectively fit together along mating edges around the electronic device. Access openings are preferably provided for the viewing screen, control wheel, touch screen, battery charger, car phone plug-in, and docking port of the electronic device. A device clip formed of thin metal material having laterally extending retaining arms biasingly engage around opposing edges of front and back covers to hold them together against the front and back of the device. A belt clip may be connected to one end of the device clip adapted for releasable attachment to a clothing article.

### CROSS-REFERENCE TO RELATED APPLICATIONS

Not applicable

### STATEMENT REGARDING FEDERALLY SPONSORED RESEARCH OR DEVELOPMENT

Not applicable

### INCORPORATION-BY-REFERENCE OF MATERIAL SUBMITTED ON A COMPACT DISC

Not applicable

### BACKGROUND OF THE INVENTION

1. Field of the Invention

This invention relates generally to small personal electronic devices which are easily carryable in hand or attached around a user's neck or to the clothing or belt of a user and more particularly to a protective enclosure for such electronic devices which is easily installable and interchangeable.

2. Description of Related Art

Small electronic devices which are hand carryable or carried on an article of clothing, or belt, or around the neck of a user are well known. Such devices include the APPLE IPOD, I Phone, GPS, hand-held computer, cameras, laptops, small portable LCD televisions, cellular phones and the like. Advances in such electronic components have facilitated extreme compactness for these electronic devices so that they may be more easily carried around a user's neck, clipped to an article of clothing or belt, shoulders trap or carried on an armband while the user engages in other activities and the like.

However, to date, the only form of protection for these electronic devices from impact or abuse is in the form of a plastic, metal, vacuum formed, leather or leatherette carrying case available for such devices. Such carrying cases are typically bulky, heavy, sometimes fragile and substantially diminish from the compactness and aesthetics of the electronic device.

The present invention provides an extremely compact, thin, yet highly impact and mar resistant covering for these electronic devices which does not inhibit the functioning of the devices, yet greatly enhances their durability and impact resistance while also offering optional aesthetics for their exterior surfaces. Another aspect of this disclosure facilitates easy connection to an article of clothing, a belt or to an armband while the electronic device is in use or simply being carried. Yet another aspect of this disclosure is the ease with which the two-part housing may be protectively installed around or removed from the electronic device for aesthetic interchange, as well as for servicing or battery replacement for the electronic device.

The foregoing examples of the related art and limitations related therewith are intended to be illustrative and not exclusive. Other limitations of the related art will become apparent to those skilled in the art upon a reading of the specification and a study of the drawings.

### BRIEF SUMMARY OF THE INVENTION

This disclosure is directed to a protective enclosure for a small hand or body carryable personal electronic device such as a well-known IPOD, miniature LCD TVs, cell phones and the like generally referred to as “IPODS” or “IPHONES”. A two-part generally rectangular housing includes front and back covers formed of high-impact thin-wall molded material and sized to protectively and closely fit together along mating edges around the IPOD electronic device. Access openings are preferably provided for the viewing screen, control wheel, battery charger, car phone plug-in and docking port of the electronic device. A device clip formed of thin metal or plastic material having laterally extending retaining arms biasingly engage around opposing edges of front and back covers to hold them together against the front and back of the device. A belt clip may be connected to one end of the device clip adapted for releasable attachment to a clothing article.

It is therefore an object of this disclosure to provide a protective housing for small compact electronic devices which is thin and streamlined and does not detract from the small compact aesthetics of the electronic device.

Still another object of this disclosure is to provide an easily interchangeable protective housing for small electronic devices which facilitates attachment to articles of clothing, belts, arm bands, hanging from the neck, and the like.

Yet another object of this disclosure is to utilize thin-walled molded carbon fiber material for high strength, impact resistance and aesthetics to form a protective housing for electronic devices which are carried by the user or on the person's clothing or around the neck of the person and without substantially altering the compactness and aesthetics of the electronic device.

The following embodiments and aspects thereof are described and illustrated in conjunction with systems, tools and methods which are meant to be exemplary and illustrative and not limiting in scope. In various embodiments one or more of the above-described problems have been reduced or eliminated while other embodiments are directed to other improvements. In addition to the exemplary aspects and embodiments described above, further aspects and embodiments will become apparent by reference of the drawings and by study of the following descriptions.

### BRIEF DESCRIPTION OF THE SEVERAL VIEWS OF THE DRAWING(S)

FIG. 1 is an exploded view of one embodiment of the disclosure.

FIG. 2 is another exploded view of FIG. 1.

FIG. 2A is a perspective view of the protective device of FIG. 1 installed around an APPLE IPOD.

FIG. 3 is a rear perspective view of FIG. 2A.

FIG. 4 is a top plan view of FIG. 3.

FIG. 5 is a bottom plan view of FIG. 3.

FIG. 6 is a cross sectional view of FIG. 2A.

FIG. 7 is a perspective section view of FIG. 2A.

Exemplary embodiments are illustrated in reference figures of the drawings. It is intended that the embodiments and figures disclosed herein are to be considered to illustrative rather than limiting.

### DETAILED DESCRIPTION OF THE INVENTION

Referring now to the drawings, the preferred embodiment of the disclosure is there shown generally at numeral 10 and includes a housing 11 formed as a two-part unit of a front cover 12 and a back cover 14 which matably engage together along common mating edges therebetween. Each of these covers 12 and 14 are molded preferably of thin (0.06″ thick) carbon fiber material for both high impact strength and natural decorative effect. However, other decorative effects may be applied by, for example painting, or the utilization of pre-colored impact-resistant moldable material.

This device 10 is intended to protectively encase a small personal electronic device or pod shown generally at I preferably in the form of an APPLE IPOD music storage and playing device which includes a viewing screen C, a circular selector dial D and battery charging, antenna connector, and docking port terminals A, B and E, respectively. These personal electronic devices which may also include miniature LCD TVs, cell phones and the like, include their own molded plastic case which is typically unornamental and/or susceptible to damage, marring and impact jarring which can affect the integrity of the internal electronic circuitry.

The front cover 12 includes a viewing screen access opening 22 which is sized to mate around the viewing screen C. Opening 24 is sized to align with the circular selector dial D of the electronic device I. Further, the access ports A, B and E are accommodated by mating slots 26/32, 28/34 and 30/54 which align and register with the corresponding ports A, B and E of the electronic device 1.

To protect the viewing screen C and the circular control D, a transparent panel 16 formed of clear LEXAN polycarbonate is preferably also provided which fits against the front surface of the electronic device 1, extending over the viewing screen C and circular control D and against the inner surface of the front cover 12.

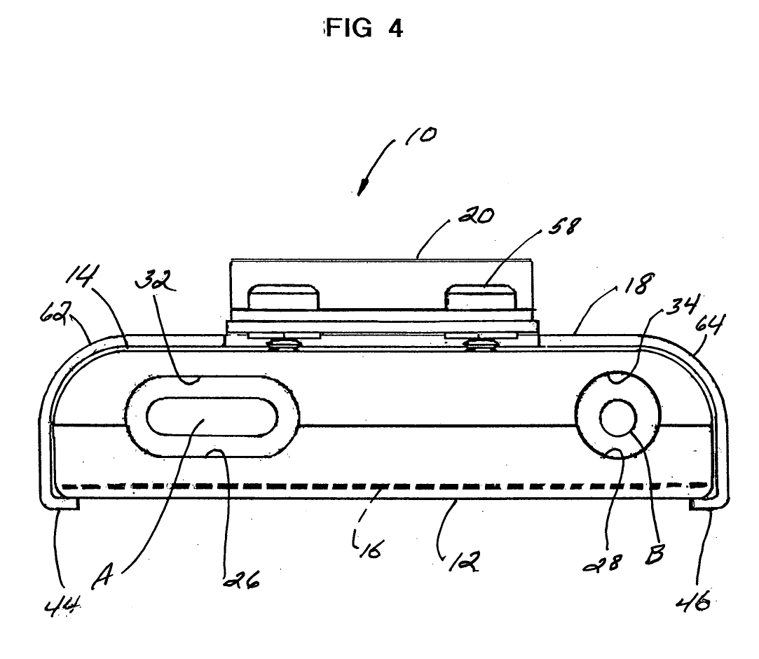

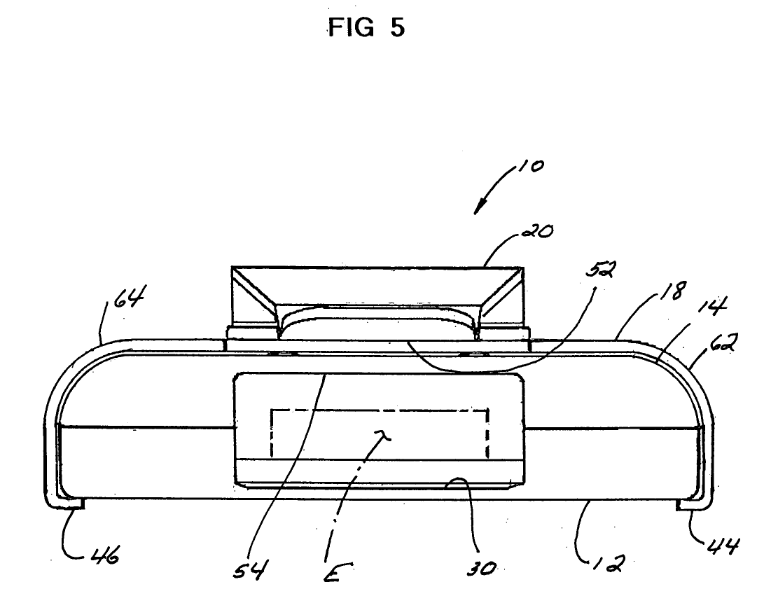

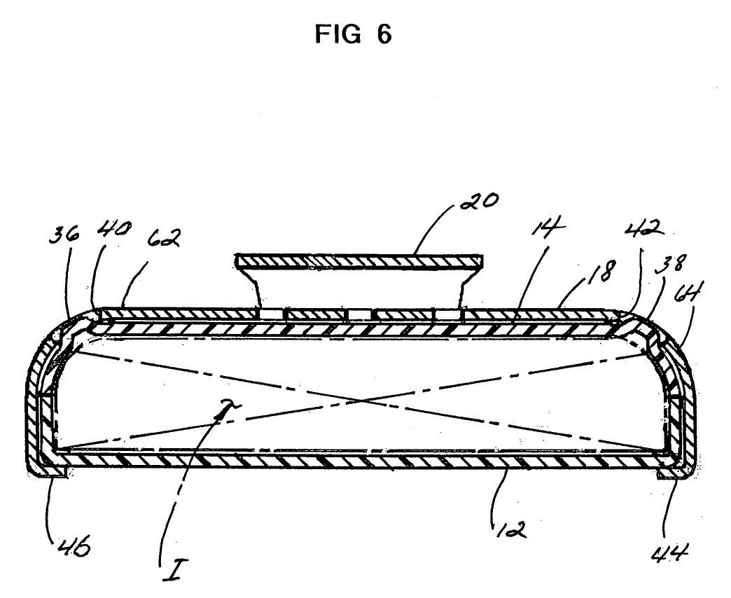

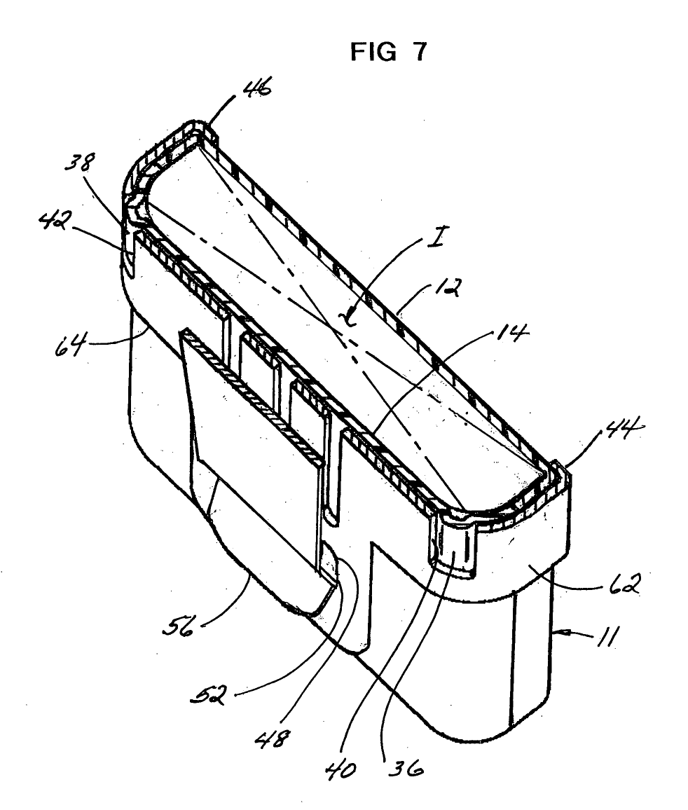

To hold the front and back covers 12 and 14 matingly together as shown, a separate spring retention or pod clip 18 is provided, again, formed of thin high-strength stainless steel material for resilience and springiness. This pod clip 18 has a generally longitudinally elongated main body and laterally extending arms 62 and 64 which terminate in inwardly extending locking flanges or tabs 44 and 46 which, as best seen in FIGS. 4 through 7, entrap a portion of the side edges of the housing 11 and hold the front and back panels 12 and 14 together. The pod clip 18 thus biasingly remains in position by these flanges 44 and 46 which are inwardly biased or sprung against the side edges of the front and back covers 12 and 14 as shown. By this arrangement, the front and back covers 12 and 14 are tightly held together by the resilient arms and associated tabs 44 and 46 of the clip 18 without the need for additional fasteners or connectors or adhesive so that the entire protective cover 10 may be easily removed and interchanged with components of different colors and textures for aesthetic purposes or for servicing of components, or batteries within the electronic device I.

To help insure that the clip 18 is securely held from longitudinal movement with respect to the front and back covers 12 and 14 when assembled, molded raised areas or beads 36 and 38 are formed and outwardly extending from the side margin of the back cover 14 and are sized to engage into slots 40 and 42, respectively, formed within the corners of the laterally extending arms 62 and 64 of clip 18.

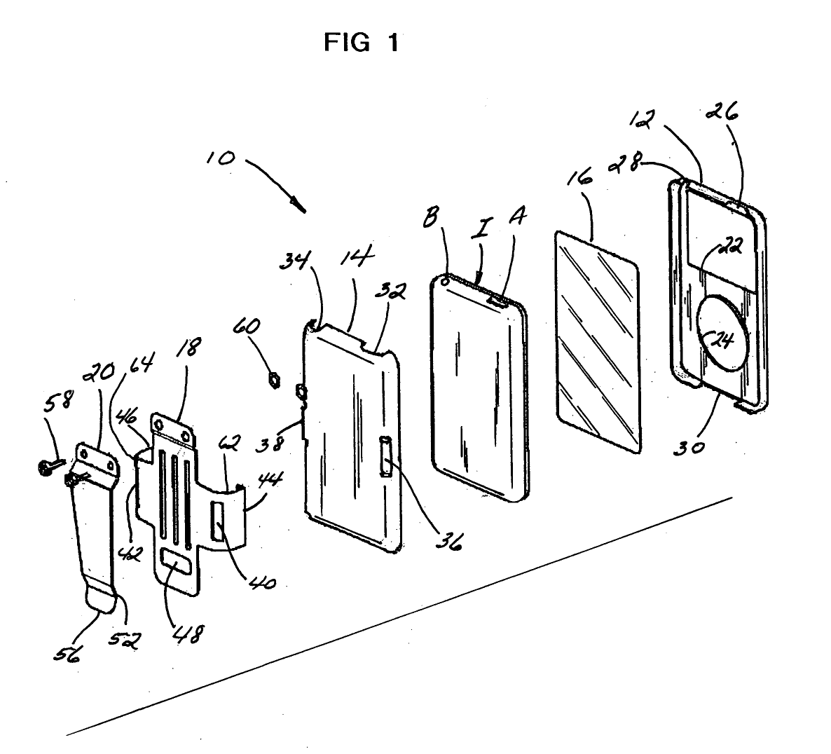

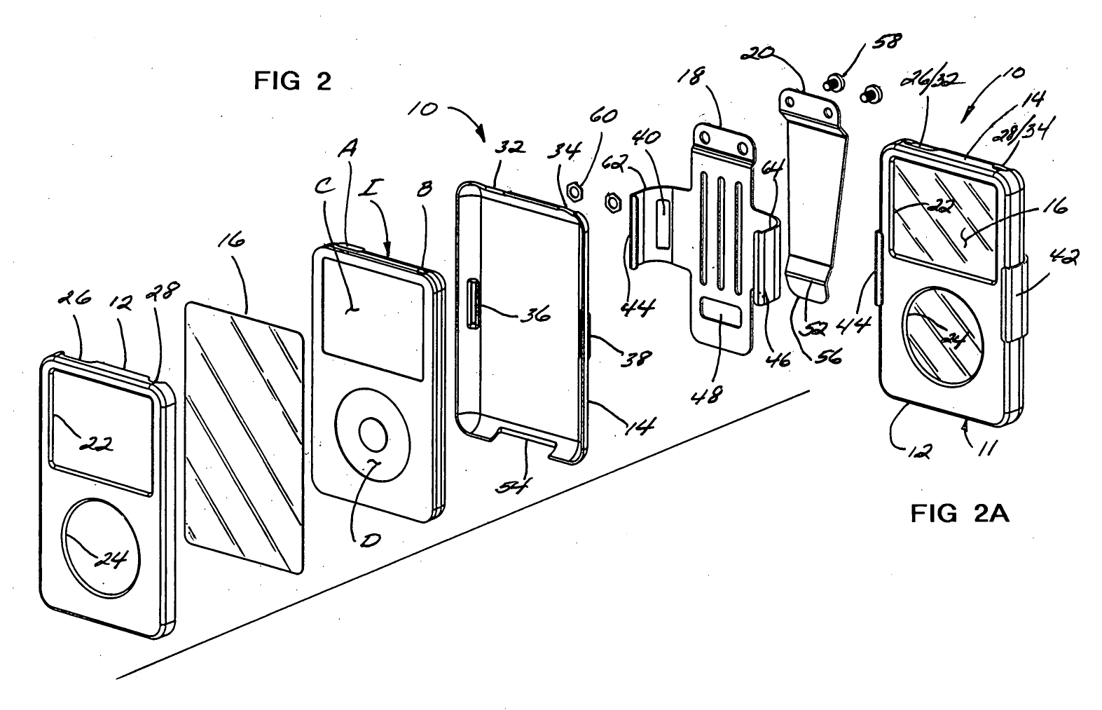

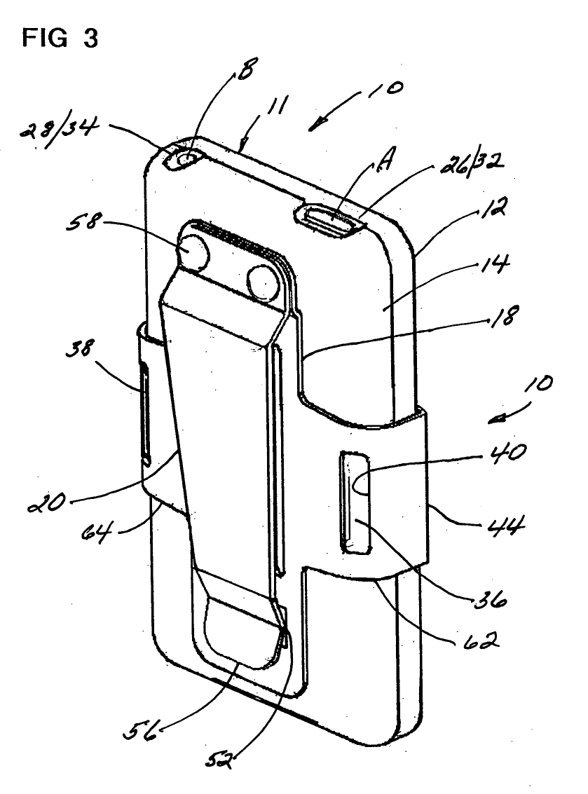

To facilitate attachment of the device 10, a belt clip 20 is held by fasteners 58 into the corresponding threaded nuts 60 positioned on either side of the top flanges of pod the clip 18 and the belt clip 20 as best seen in FIGS. 1 and 2.

Note that the distal end 56 of the belt clip 20 at 52 biasingly engages against the outer surface of the back cover 14 and into apertures 48 to enhance the releasable engagement over a waist belt or armband.

While a number of exemplary aspects and embodiments have been discussed above, those of skill in the art will recognize certain modifications, permeations and additions and subcombinations thereof. It is therefore intended that the following appended claims and claims hereinafter introduced are interpreted to include all such modifications, permeations, additions and subcombinations that are within their true spirit and scope.

1. A protective enclosure for a hand or body carryable personal electronic device comprising:
a two-part generally rectangular housing including a front and a back cover formed of high-impact thin-wall molded material and being adapted in size to closely protectively fit together along mating edges around the electronic device;
said front cover including access openings providing viewing access to a view screen and adjusting access to a control wheel of the electronic device;
said front and/or back covers including end or side access openings adapted for battery charger, car phone plug-in, and/or a docking port access;
a pod clip formed of thin metal material having laterally extending retaining arms which biasingly engage around opposing edges of said front and back covers to hold said front and back covers together against a front and a back, respective, of the electronic device;
a belt clip connected to said device clip and being adapted for releasable attachment of said housing to a clothing article.

2. A protective enclosure as set forth in claim 1, wherein:
said front and back covers are each formed of a single sheet of carbon fiber material.

3. A protective enclosure as set forth in claim 1, further comprising:
a flat transparent protective panel positioned within said housing against an inner surface of said front cover and protectively against the viewing screen and control wheel of the electronic device.

4. A protective enclosure as set forth in claim 3, wherein:
a side margin of said housing includes a raised bead which biasingly engages into a locking aperture formed through one of said retaining arms to prevent relative lengthwise sliding movement between said device clip and said housing.

5. A protective enclosure for an IPOD-type personal electronic device comprising:
a two-part generally rectangular housing including a front and a back cover formed of high-impact thin-wall molded material and being adapted in size to closely protectively fit together along mating edges around the electronic device;
said front cover including access openings providing viewing access to a view screen and adjusting access to a control wheel of the electronic device;
said housing including end access openings adapted to provide access to battery charger, car phone plug-in, a docking port access, and interconnection thereof to the electronic device;
an elongated pod clip formed of thin metal material having laterally extending retaining arms which biasingly engage around opposing edges of said front and back covers to hold said device clip against said back cover and to hold said front and back covers together against a front and a back, respective, of the device;
a belt clip connected to, and being generally coextensive with a length of said pod clip, said belt clip being adapted for releasable attachment of said housing to a clothing article.

6. A protective enclosure as set forth in claim 5, wherein:
said front and back covers are each formed of a single sheet of carbon fiber material.

7. A protective enclosure as set forth in claim 5, further comprising:
a flat transparent protective panel positioned within said housing against an inner surface of said front cover and protectively against the viewing screen and control wheel of the electronic device.

8. A protective enclosure as set forth in claim 7, wherein:
a side margin of said housing includes a raised bead which biasingly engages into a locking aperture formed through one of said retaining arms to prevent relative lengthwise sliding movement between said device clip and said housing.

9. A protective enclosure for a hand, body or clothing carryable personal electronic device comprising:
a two-part generally rectangular housing including a front and a back cover each formed of high-impact thin-wall molded material and being adapted in size to closely protectively fit together along mating edges around the electronic device;
said front cover including an access opening providing viewing access to a view screen and another access opening for a control wheel of the electronic device;
said housing also including end or side access openings adapted for battery charger, car phone plug-in, and/or a docking port connection to the electronic device therethrough;
an elongated pod clip formed of thin metal material having laterally extending retaining arms which biasingly engage around and entrap opposing edges of said front and back covers to hold said front and back covers together and against a front and a back, respective, of the electronic device.

10. A protective enclosure as set forth in claim 9, wherein:
said front and back covers are each formed of a single sheet of carbon fiber material.

11. A protective enclosure as set forth in claim 9, further comprising:
a flat transparent protective panel positioned within said housing against an inner surface of said front cover and protectively against the viewing screen and control wheel of the electronic device.

12. A protective enclosure as set forth in claim 11, wherein:
a side margin of said housing includes a raised bead which biasingly engages into a locking aperture formed through one of said retaining arms to prevent relative lengthwise sliding movement between said pod clip and said housing.

13. A protective enclosure as set forth in claim 9, further comprising:
a belt clip connected at one end thereof to a corresponding end of said pod clip and generally coextensive therewith, said belt clip being adapted for releasable dependent attachment of said housing to a clothing article.
